(19) United States
(12) Patent Application Publication
(10) Pub. No.: US 2023/0371187 A1
(43) Pub. Date: Nov. 16, 2023

(54) PACKAGE SUBSTRATE STRUCTURE

(71) Applicant: AMAZING COOL TECHNOLOGY CORPORATION, Taipei City (TW)

(72) Inventors: Shiann-Tsong TSAI, Taipei City (TW); Yang-Ming SHIH, Taipei City (TW); Hung-Yun HSU, Taipei City (TW)

(21) Appl. No.: 18/315,735

(22) Filed: May 11, 2023

(30) Foreign Application Priority Data
May 12, 2022 (TW) 111117855

(51) Int. Cl. H05K 3/38; H05K 1/09

(52) U.S. Cl. CPC H05K 3/388; H05K 1/092; H05K 2201/0323; H05K 2201/0338

(57) ABSTRACT

A package substrate structure includes a substrate, a metal base layer, a build-up film, a bonding layer, and a wiring unit. The metal base layer is disposed on the substrate. The build-up film is disposed on the metal base layer and is formed with trenches to expose the metal base layer. The build-up film includes an insulating material. The bonding layer is disposed on the build-up film and includes a graphene-metal composite. The graphene-metal composite includes a metal matrix, and a plurality of graphene nanostructures dispersed in the metal matrix and arranged among lattices of the metal matrix. The graphene nanostructures form covalent bonds with each other. The wiring unit is bonded to the build-up film through the bonding layer and fills the trenches so as to be electrically connected to the metal base layer. The wiring unit is formed with a wiring pattern on the build-up film.

### CROSS-REFERENCE TO RELATED APPLICATION

This application claims priority to Taiwanese Invention Patent Application No. 111117855, filed on May 12, 2022.

### FIELD

The disclosure relates to a package substrate structure, and more particularly to a package substrate structure for an electronic component in which a build-up film and a wiring unit can be bonded satisfactorily and insertion loss can be reduced effectively.

### BACKGROUND

With the advancement of technology, electronic products have been developing in a trend of reduced size and weight, high power, high frequency, and low power consumption. Therefore, requirements for a package substrate structure used to support various electronic components in the electronic products are getting higher and higher so as to meet packaging requirements of high integration and miniaturization.

In fifth-generation (5G) high-frequency communication technology, an Ajinomoto build-up film (ABF) with low dielectric constant (Dk) and low dissipation factor (Df) is commonly used for manufacturing a package substrate structure which is suitable for mounting chips requiring fine wiring, high pin count, and high message transmission.

In an existing method for manufacturing a package substrate structure, after the Ajinomoto build-up film is disposed on a substrate, the Ajinomoto build-up film is roughened to increase surface roughness thereof prior to formation of conductive wiring by disposing metal (for example, copper) thereon so as to tightly bond the metal and the Ajinomoto build-up film to each other.

However, in high-frequency signal/circuit applications, insertion loss is increased with increase of frequency due to a skin effect at a surface of a conductive material. Therefore, when the surface roughness of the Ajinomoto build-up film is increased, impedance of subsequent high-frequency signal is easily increased.

### SUMMARY

Therefore, an object of the disclosure is to provide a package substrate structure for an electronic component that can alleviate at least one of the drawbacks of the prior art.

According to the disclosure, the package substrate structure includes a substrate, a metal base layer, a build-up film, a bonding layer, and a wiring unit. The metal base layer is disposed on the substrate. The build-up film is disposed on the metal base layer and is formed with a plurality of trenches to expose the metal base layer. The build-up film includes an insulating material. The bonding layer is disposed on the build-up film and includes a graphene-metal composite. The graphene-metal composite includes a metal matrix, and a plurality of graphene nanostructures dispersed in the metal matrix and arranged among lattices of the metal matrix. The graphene nanostructures form covalent bonds with each other. The wiring unit is bonded to the build-up film through the bonding layer and fills the trenches so as to be electrically connected to the metal base layer. The wiring unit is formed with a wiring pattern on the build-up film.

In the package substrate structure of the disclosure, the wiring unit can be bonded to the build-up film satisfactorily through the bonding layer including the graphene-metal composite without roughening the surface of the build-up film. Therefore, the skin effect occurred in the prior art due to roughening of the surface of the build-up film can be overcome, such that the insertion loss produced due to the skin effect can be reduced effectively.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic view illustrating an embodiment of a package substrate structure according to the disclosure.

FIG. 2 is a flow diagram illustrating a method for manufacturing the package substrate structure illustrated in FIG. 1.

FIGS. 3 to 8 are schematic views illustrating some intermediate stages of the method as depicted in FIG. 2.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

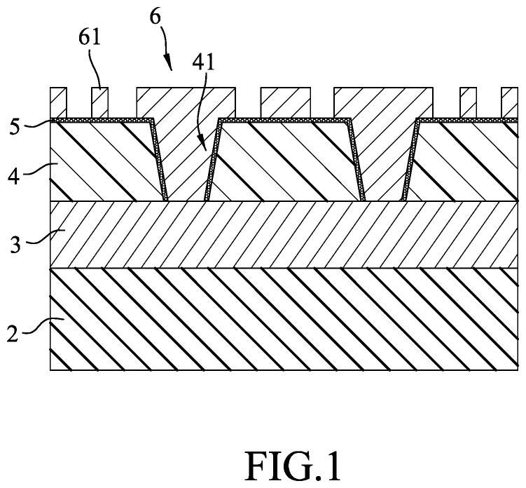

Referring to FIG. 1, an embodiment of a package substrate structure according to the disclosure includes a substrate 2, a metal base layer 3, a build-up film 4, a bonding layer 5, and a wiring unit 6.

The substrate 2 may be made of, for example, but not limited to, an epoxy-based material which may include, for example, but not limited to, epoxy resin, a composite of epoxy resin and glass fibers, a composite of epoxy resin and fillers, or combinations thereof.

The metal base layer 3 is disposed on the substrate 2, and may be made of a metal material which may include, for example, but not limited to, copper (Cu), titanium (Ti), nickel (Ni), gold (Au), palladium (Pa), tin (Sn), and combinations thereof.

The build-up film 4 is disposed on the metal base layer 3 and is formed with a plurality of trenches 41 to expose the metal base layer 3. The build-up film 4 includes an insulating material. In some embodiments, the build-up film 4 is made of a dielectric insulating material having Dk/Df of less than 3.8/0.015, wherein Dk is a dielectric constant and Df is a dissipation factor. The surface of the build-up film 4 is not subjected to a roughening process, and thus is smooth. In the embodiment, the build-up film 4 is illustrated by an Ajinomoto build-up film.

The bonding layer 5 is disposed on the build-up film 4 and includes a graphene-metal composite. The graphene-metal composite includes a metal matrix, and a plurality of graphene nanostructures (for example, but not limited to, graphene nanoplatelets) dispersed in the metal matrix and arranged among lattices of the metal matrix. The graphene nanostructures form covalent bonds with each other. In addition, the graphene nanostructures and the metal matrix are bonded with each other through covalent bonds formed thereamong. In some embodiments, the graphene nanostructures are present in an amount ranging from 0.02 wt % to 3.00 wt % based on a total weight of the graphene-metal composite. In some embodiments, the graphene-metal composite has an oxygen content of up to 10 ppm. In some embodiments, the graphene-metal composite has a thermal conductivity of up to 460 W/mK. In some embodiments, the metal matrix included in the graphene-metal composite may include a metal material, for example, but not limited to, copper (Cu), aluminum (Al), gold (Au), silver (Ag), platinum (Pt), palladium (Pd), tin (Sn), and combinations thereof. In the embodiment, the metal material for the metal matrix is illustrated by copper, and thus the graphene-metal composite is illustrated by a graphene-copper composite.

The wiring unit 6 is bonded to the build-up film 4 through the bonding layer 5 and fills the trenches 41 so as to be electrically connected to the metal base layer 3. The wiring unit 6 is formed with a wiring pattern 61 on the build-up film 4. In some embodiments, the wiring unit 6 may be made of a metal material, for example, but not limited to, copper (Cu), titanium (Ti), nickel (Ni), gold (Au), palladium (Pd), tin (Sn), and combinations thereof. In the embodiment, the metal material for forming the wiring unit 6 is illustrated by copper.

In the package substrate structure of the disclosure, the wiring unit 6 can be bonded to the build-up film 4 satisfactorily through the bonding layer 5 including the graphene-metal composite without roughening the surface of the build-up film 4. Therefore, the skin effect occurred in the prior art due to roughening of the surface of the build-up film 4 can be overcome, such that the insertion loss produced due to the skin effect can be reduced effectively.

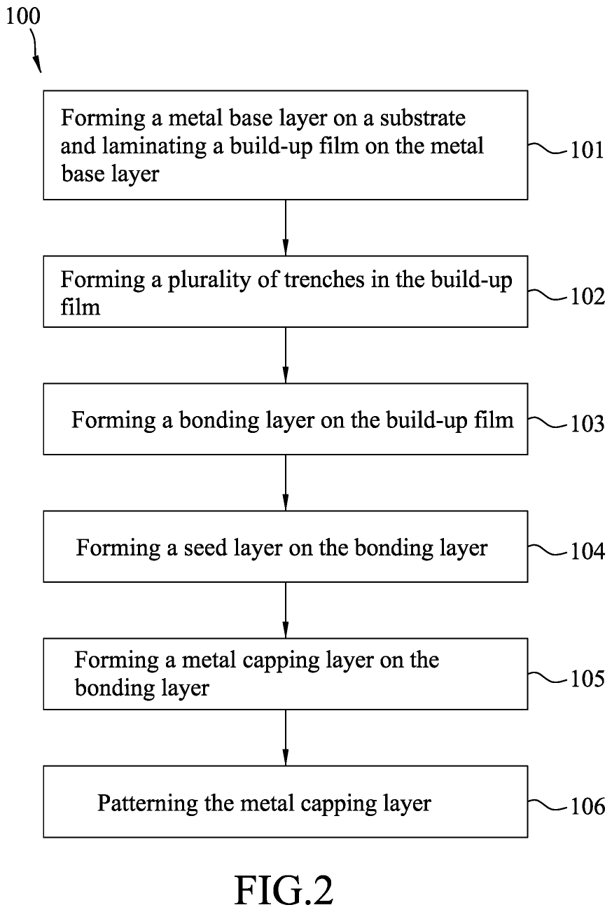

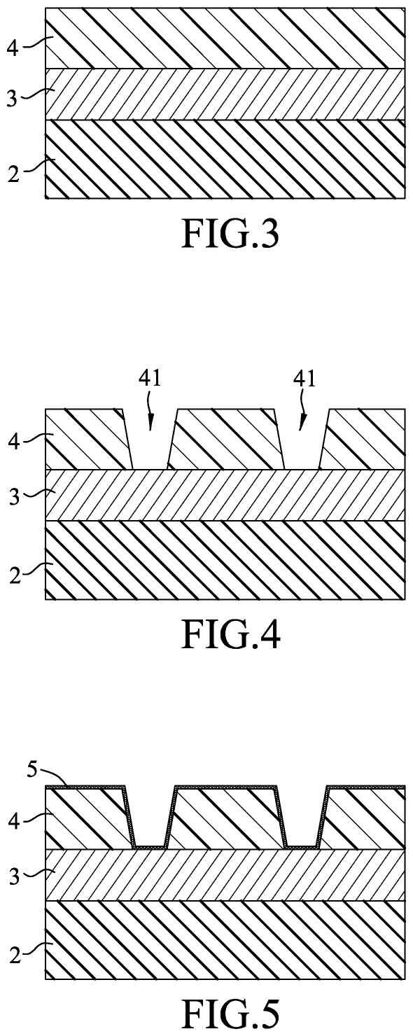

Referring to FIGS. 2 and 3, a method 100 for manufacturing the package substrate structure illustrated in FIG. 1 begins at step 101. In step 101, the metal base layer 3 is formed on the substrate 2, and the build-up film 4 (for example, an Ajinomoto build-up film) is then laminated on the metal base layer 3.

Referring to FIGS. 2 and 4, the method 100 proceeds to step 102. In step 102, the build-up film 4 is patterned by, for example, but not limited to, excimer laser to form a plurality of the trenches 41 to expose the metal base layer 3.

Referring to FIGS. 2 and 5, the method 100 proceeds to step 103. In step 103, the bonding layer 5 is conformally formed on the build-up film 4 and portions of the metal base layer 3 exposed from the trenches 41 shown in FIG. 4 by, for example, but not limited to, sputtering or plating the graphene-metal composite on a smooth surface of the build-up film 4 and surfaces of the portions of the metal base layer 3. In some embodiments, a cleaning process (for example, but not limited to, a desmear process) may be optionally conducted to clean the surface of the build-up film 4 and the surfaces of the portions of the metal base layer 3 prior to formation of the bonding layer 5 on the build-up film 4 and the portions of the metal base layer 3.

Referring to FIGS. 2 and 6, the method 100 proceeds to step 104. In step 104, a seed layer 60 is formed on the bonding layer 5 by, for example, depositing or plating a metal material (for example, but not limited to, copper) on the bonding layer 5.

Referring to FIGS. 2 and 7, the method 100 proceeds to step 105. In step 105, a metal capping layer 62 is formed on the bonding layer 5 by, for example, removing portions of the seed layer 60 and portions of the bonding layer 5 corresponding to the trenches 41 in positions shown in FIG. 6, and depositing or plating the metal material (for example, but not limited to, copper) on the seed layer 60 and the portions of metal base layer 3 exposed from the trenches 41, such that the metal capping layer 62 fills the trenches 41 so as to be electrically connected to the metal base layer 3.

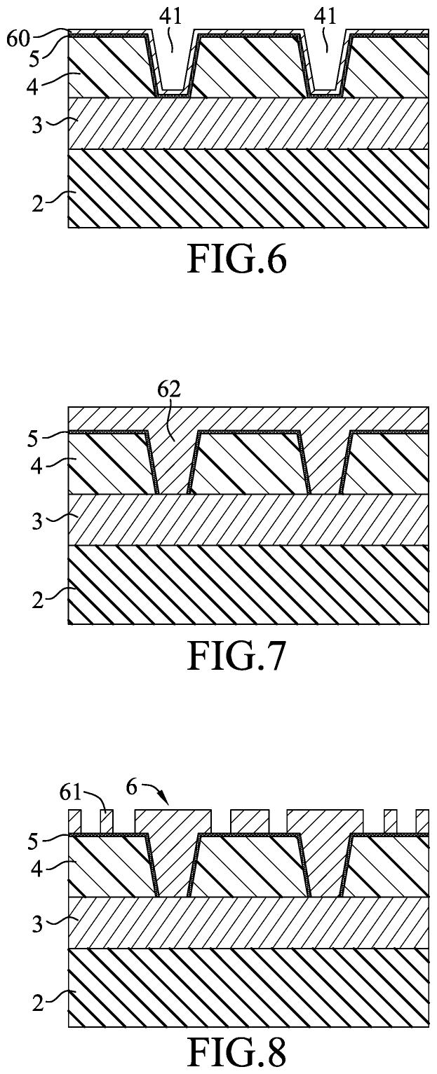

Referring to FIGS. 2 and 8, the method 100 proceeds to step 106. In step 106, the metal capping layer 62 shown in FIG. 7 is patterned by, for example, but not limited to, a photolithography process to form the wiring unit 6. The wiring unit 6 is formed with the wiring pattern 61 on the build-up film 4.

In summary, in the package substrate structure of the disclosure, the wiring unit can be bonded to the build-up film satisfactorily through the bonding layer including the graphene-metal composite without roughening the surface of the build-up film. Therefore, the skin effect occurred in the prior art due to roughening of the surface of the build-up film can be overcome, such that the insertion loss produced due to the skin effect can be reduced effectively.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A package substrate structure, comprising:
a substrate;
a metal base layer disposed on said substrate;
a build-up film disposed on said metal base layer and formed with a plurality of trenches to expose said metal base layer, said build-up film including an insulating material;
a bonding layer disposed on said build-up film and including a graphene-metal composite, said graphene-metal composite including a metal matrix, and a plurality of graphene nanostructures dispersed in said metal matrix and arranged among lattices of said metal matrix, said graphene nanostructures forming covalent bonds with each other; and
a wiring unit bonded to said build-up film through said bonding layer and filling said trenches so as to be electrically connected to said metal base layer, said wiring unit being formed with a wiring pattern on said build-up film.

2. The package substrate structure as claimed in claim 1, wherein said graphene nanostructures are present in an amount ranging from 0.02 wt % to 3.00 wt % based on a total weight of said graphene-metal composite, and said graphene-metal composite has an oxygen content of up to 10 ppm.

3. The package substrate structure as claimed in claim 1, wherein said metal matrix includes a metal material selected from a group consisting of copper, aluminum, gold, silver, platinum, palladium, tin, and combinations thereof.

4. The package substrate structure as claimed in claim 1, wherein said graphene-metal composite has a thermal conductivity of up to 460 W/mK.

5. The package substrate structure as claimed in claim 1, wherein said build-up film includes a dielectric insulating material having Dk/Df of less than 3.8/0.015, wherein Dk is a dielectric constant and Df is a dissipation factor.

6. The package substrate structure as claimed in claim 1, wherein each of said metal base layer and said wiring unit independently includes a metal material selected from a group consisting of copper, titanium, nickel, gold, palladium, tin, and combinations thereof.
